(19) United States
(12) Patent Application Publication
(10) Pub. No.: US 2018/0350878 A1
(43) Pub. Date: Dec. 6, 2018

(54) Method and Apparatus for a Transmission Gate for Multi-GB/s Application

(71) Applicants: Yonggang Chen, Duluth, GA (US); Shriram Kulkarni, Duluth, GA (US); Prashant Shamarao, Duluth, GA (US)

(72) Inventors: Yonggang Chen, Duluth, GA (US); Shriram Kulkarni, Duluth, GA (US); Prashant Shamarao, Duluth, GA (US)

(73) Assignee: Integrated Device Technology, Inc., San Jose, CA (US)

(21) Appl. No.: 13/244,429

(22) Filed: Sep. 24, 2011

(51) Int. Cl. H01L 27/24; H01H 9/50

(52) U.S. Cl. CPC H01L 27/24; H01H 9/50

(57) ABSTRACT

A Method and Apparatus for a Transmission Gate for Multi-GB/s Application have been disclosed. By actively biasing the gate and body of both NFET and PFET improved performance is achieved.

### FIELD OF THE INVENTION

The present invention pertains to transmission gates. More particularly, the present invention relates to a Method and Apparatus for a Transmission Gate for Multi-GB/s Application.

### BACKGROUND OF THE INVENTION

Transmission gates are used as switches widely in both analog and digital circuit design, however with increasing operating speed the inherent bandwidth limitation of a transmission gate limits its application from high speed communication. To make the transmission gate on-resistance small, the sizes of transistors used in the transmission gate need to be large, but this will increase the capacitive load, which will reduce the bandwidth. This presents a technical problem which needs a technical solution.

In multi-Giga BPS (bit per second) applications, like for example, but not limited to, a multiplexer for PCIe (Peripheral Component Interconnect Express) and for DisplayPort, an active switch is often used, like a CML (Common Mode Logic) circuit, which has good bandwidth but consumes a lot of power compared to a passive transmission gate type switch. This presents a technical problem which needs a technical solution.

Thus there is a need for a technical solution to this technical problem. What is needed is a transmission gate which has reduced load capacitance and can be used in multi-Giga BPS while being power efficient. An ideal solution would also reduce the on resistance of the transmission gate.

### BRIEF DESCRIPTION OF THE DRAWINGS

The invention is illustrated by way of example and not limitation in the figures of the accompanying drawings in which:

FIG. 1 illustrates a network environment in which the method and apparatus of the invention may be implemented;

FIG. 2 is a block diagram of a computer system in which some embodiments of the invention may be used;

FIG. 3 illustrates one embodiment of the invention where the transmission gate is in the OFF state;

FIG. 4 illustrates one embodiment of the invention where the switch (transmission gate) is in the ON state;

FIG. 5 illustrates one embodiment of the invention showing the ON/OFF states for the NFET and PFET;

FIG. 6 illustrates an NFET ON state equivalent circuit;

FIG. 7 shows various embodiments of the invention; and

FIG. 8 shows various embodiments of the invention.

### DETAILED DESCRIPTION

In one embodiment of the invention, using the disclosed techniques a transmission gate is modified to reduce the load capacitance, and therefore it can be used in multi-Giga BPS communication, thereby allowing the switching of the high speed signals to be much simpler and power efficient.

In one embodiment of the invention the approach to improve the bandwidth of a transmission gate is to reduce on resistance and load capacitance simultaneously. An efficient solution is achieved in the present invention.

In one embodiment of the invention a unique approach is used to create different paths for the transmission gate at ON and OFF state. For example, in one embodiment, at ON state the gate capacitance will be connected in series with a “high” impedance component so that the load capacitance due to the gate capacitance will be reduced dramatically.

In one embodiment of the invention, at ON state the body of a transistor is connected to the source through a high impedance so the effective load to signal path by the channel to body capacitance will change to a series of channel to body capacitance and body to N-well-to-p-sub capacitance for an NFET (n-type field effect transistor).

In one embodiment of the invention, at ON state the body of a transistor is connected to the source through a high impedance so the effective load to signal path by the channel to body capacitance will change to a series of channel to body capacitance and p-body to deep N-well capacitance for a PFET (p-type field effect transistor).

In one embodiment of the invention, the body of a transistor is connected to the source through a high impedance so the effective load to signal path by the channel to body capacitance will change to a series of channel to body capacitance and body to N-well-to-p-sub capacitance for an NFET (n-type field effect transistor) at ON state, and p-body to deep N-well capacitance for a PFET (p-type field effect transistor) at ON state.

In one embodiment of the invention the transmission gate is built with a standard NWELL CMOS (n-type well complementary metal-oxide-semiconductor) process with a deep N-well option.

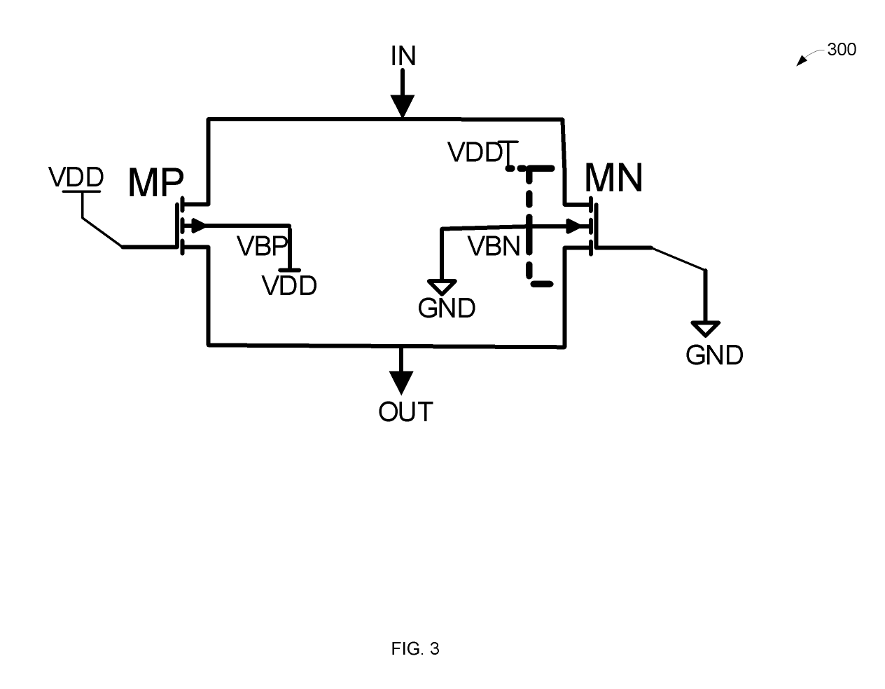

FIG. 3 illustrates, generally at 300, one embodiment of the invention where the switch (transmission gate) is in the OFF state.

In the OFF state, the transmission gate has high resistance (ideally infinite) between source and drain, and load capacitance at the source/drain side is a combination of source/drain gate overlap capacitance and source/drain junction capacitance. The gate and the body terminal (body) are both biased by low impedance to AC (alternating current) ground, so the voltage at these nodes will not change with a signal at either input or output, this helps to keep the transmission gate in a strong OFF state and keep good isolation between input and output.

VDD denotes a supply voltage not at a ground potential. MP denotes a p-type FET (PFET), VBP denotes a body voltage bias for PFET. MN denotes an n-type FET (NFET), VBN denotes a body voltage bias for NFET. GND denotes ground. IN denotes input. OUT denotes output. Rg denotes a resistance to a gate. Rb denotes a resistance to a body.

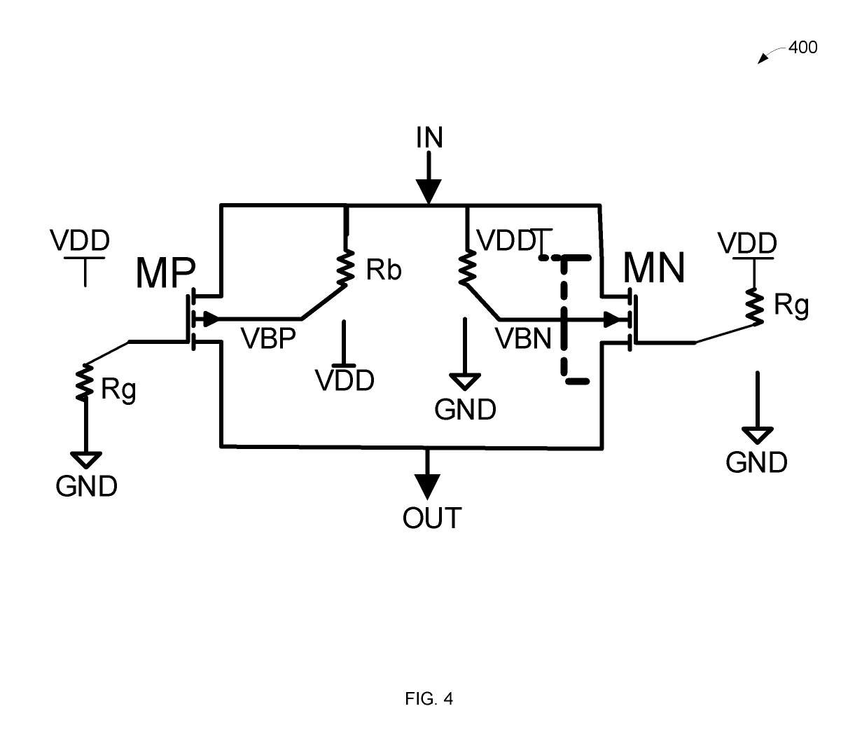

FIG. 4 illustrates, generally at 400, one embodiment of the invention where the switch (transmission gate) is in the ON state. As illustrated, and as can be clearly seen, this state effectively reduces the body effect for a signal at all levels and isolates the gate capacitance from the signal path, and also reduces the load effect due to the channel to body capacitance.

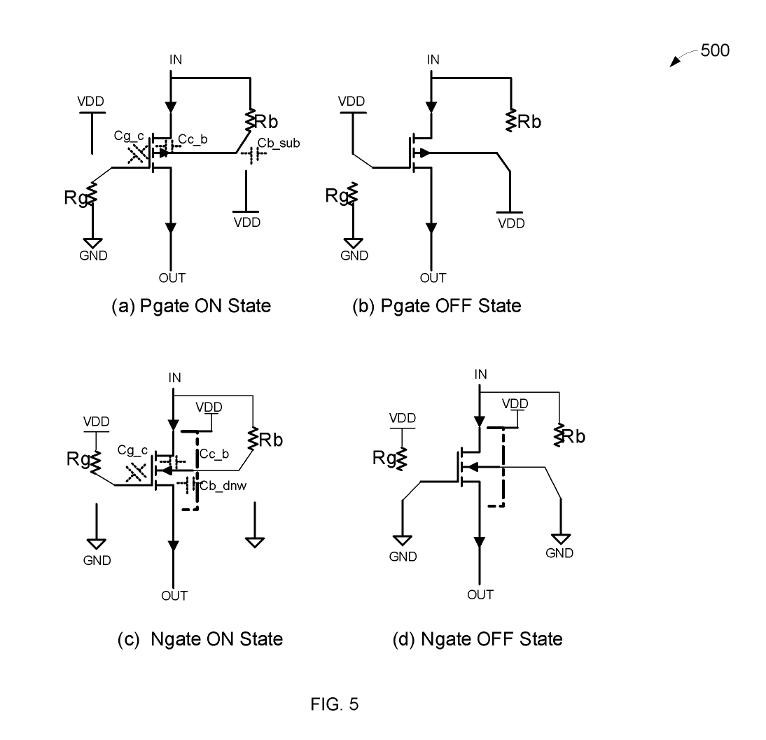

FIG. 5 illustrates, generally at 500, one embodiment of the invention showing the ON/OFF states for the NFET and PFET respectively (at (c), (a), (d), and (b) respectively). The OFF state of the transmission gate is shown in (b) and (d).

We will now analyze the ON state of the NFET as shown in FIG. 5 at (c). Note that a similar analysis applies to the PFET and will not be repeated here as one of skill in the art will appreciate the similar analysis. The deep N-well terminal is always connected to a power supply (VDD), which is AC ground. Rg is a resistance with a value much larger than the impedance of the gate capacitance at the interested frequency. Rb is a resistance with a value much larger than the impedance of the channel to body capacitance.

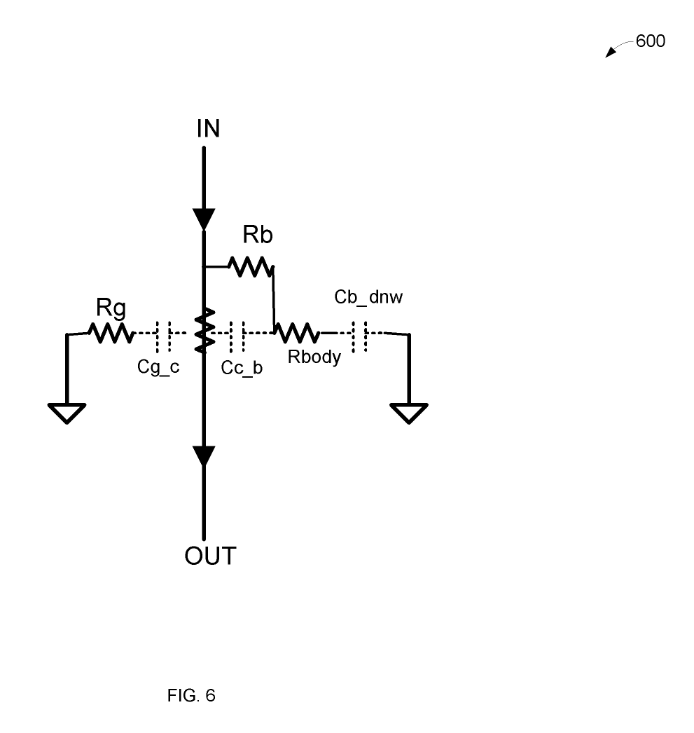

FIG. 6 illustrates, generally at 600, an NFET ON state equivalent circuit, where Cg-c is the gate to channel capacitance, Cc-b is the channel to body capacitance including the source/drain junction capacitance, Cb-dnw is the body to deep N-well capacitance and Rbody is a distributed body resistance inside the NFET. Rg and Rb in one embodiment of the invention are poly (polysilicon) resistors. At or below the interested frequency, the resistance of Rg is much larger than the impedance of Cg-c, and the resistance of Rb is much larger than the impedance of Cc-b. So the Rb path can be neglected compared to Cc-b, and another signal path through Cg-c and Rg can also be neglected for first order analysis. As results, the total load capacitance seen from the main signal path is composed of Cc-b in series with Rbody and Cb-dnw, the equivalent impedance is much larger than that of the sum of Cg-c and Cc-b (as may be seen in a traditional transmission gate).

For an ON resistance of a MOSFET (metal oxide semiconductor field effect transistor), the deterministic parameter is overdrive voltage besides device parameters. The overdrive voltage is a voltage difference between the gate to source voltage and the threshold voltage. A larger W/L (width/length) of the device gives lower ON resistance, and larger overdrive also reduces the ON resistance. Maximum gate to source voltage is limited by a power supply voltage and the maximum voltage a device allows, which is generally dependent on the semiconductor process a designer uses. The change of the gate to source voltage changes the ON resistance.

The ON resistance changes with a continuous signal level and will cause distortion, so keeping the ON resistance a fixed value is very important for a transmission gate to be used to pass a continuous signal. In this invention, in one embodiment, as shown in FIG. 5 at (c), when the signal at the input is changing at a high frequency, the voltage divider formed by Rg and Cg-c, and the voltage at the gate will follow the input signal due to Rg being a high impedance at the interested frequency. Therefore the gate to source voltage will not change with the signal level and the ON resistance value keeps at a constant. This feature of the present invention makes the transmission gate not require AC coupling, which helps to reduce application costs.

Body effect is another factor to determine the overdrive voltage, this invention, in one embodiment of the invention, biases the body of the MOSFET at the same level as the signal common-mode. Rb provides a DC path from the input to body connection, so no DC difference exists between the body and the source, which removes the ON resistance changes due to signal common-mode level.

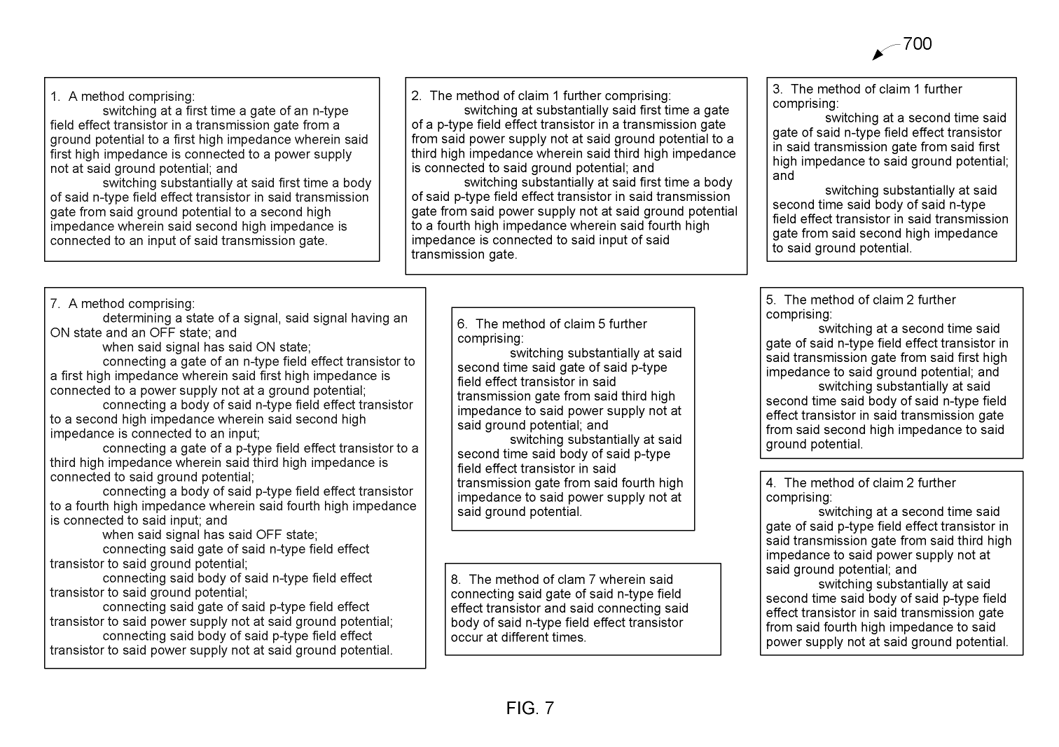

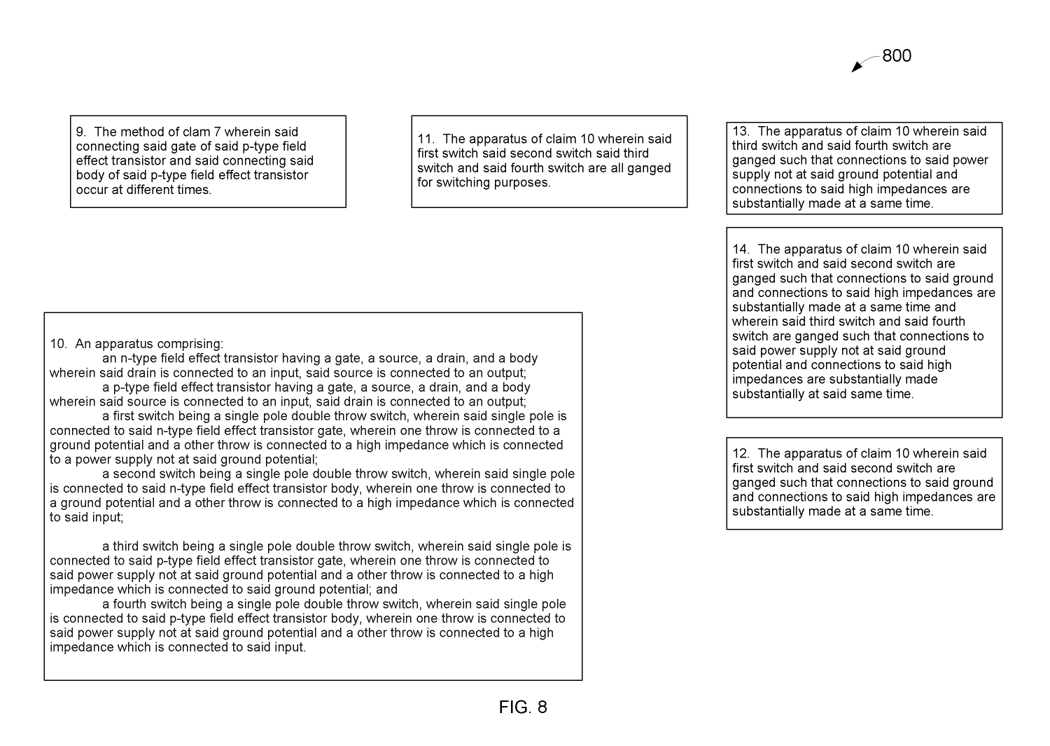

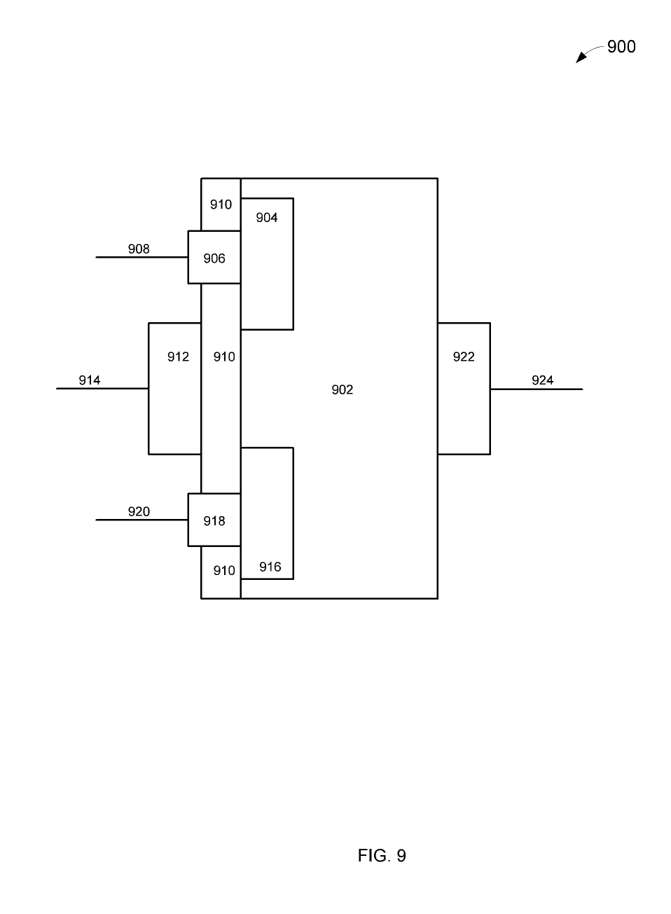

FIG. 7 and FIG. 8 illustrate various embodiment of the invention.

Thus a method and apparatus for a transmission gate for multi-gb/s application have been described.

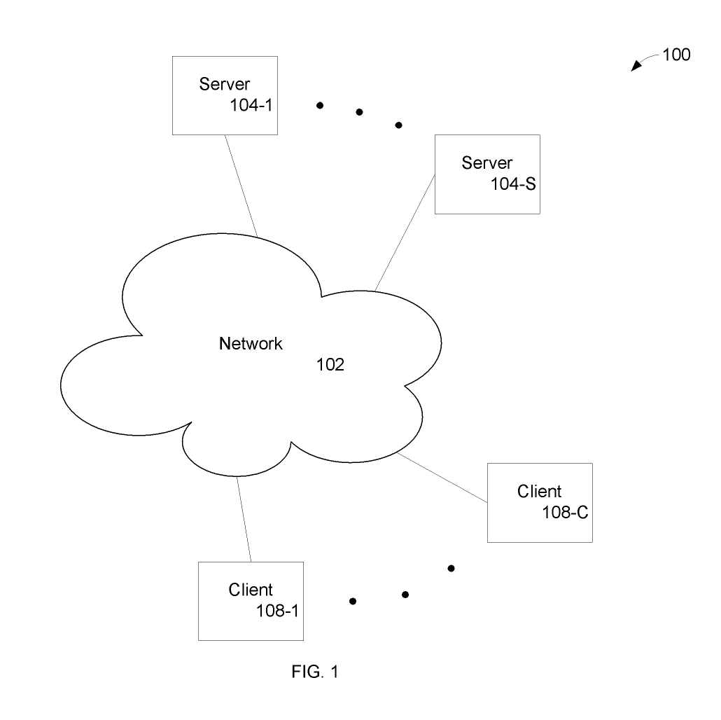

FIG. 1 illustrates a network environment 100 in which the techniques described may be applied. The network environment 100 has a network 102 that connects S servers 104-1 through 104-S, and C clients 108-1 through 108-C. More details are described below.

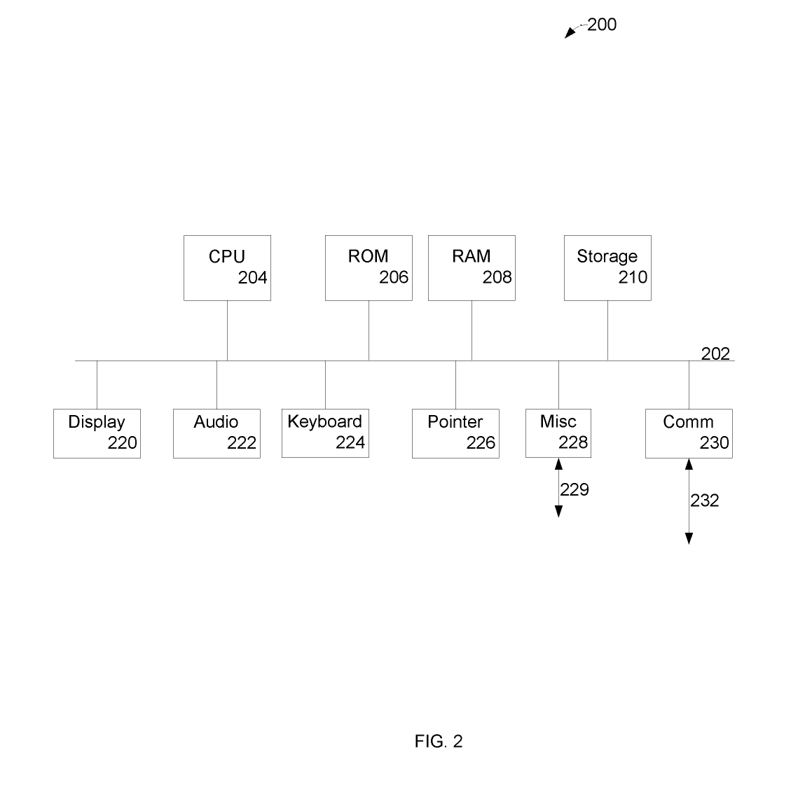

FIG. 2 is a block diagram of a computer system 200 in which some embodiments of the invention may be used and which may be representative of use in any of the clients and/or servers shown in FIG. 1, as well as, devices, clients, and servers in other Figures. More details are described below.

Referring back to FIG. 1, FIG. 1 illustrates a network environment 100 in which the techniques described may be applied. The network environment 100 has a network 102 that connects S servers 104-1 through 104-S, and C clients 108-1 through 108-C. As shown, several computer systems in the form of S servers 104-1 through 104-S and C clients 108-1 through 108-C are connected to each other via a network 102, which may be, for example, a corporate based network. Note that alternatively the network 102 might be or include one or more of: the Internet, a Local Area Network (LAN), Wide Area Network (WAN), satellite link, fiber network, cable network, or a combination of these and/or others. The servers may represent, for example, disk storage systems alone or storage and computing resources. Likewise, the clients may have computing, storage, and viewing capabilities. The method and apparatus described herein may be applied to essentially any type of visual communicating means or device whether local or remote, such as a LAN, a WAN, a system bus, etc. Thus, the invention may find application at both the S servers 104-1 through 104-S, and C clients 108-1 through 108-C.

Referring back to FIG. 2, FIG. 2 illustrates a computer system 200 in block diagram form, which may be representative of any of the clients and/or servers shown in FIG. 1. The block diagram is a high level conceptual representation and may be implemented in a variety of ways and by various architectures. Bus system 202 interconnects a Central Processing Unit (CPU) 204, Read Only Memory (ROM) 206, Random Access Memory (RAM) 208, storage 210, display 220, audio 222, keyboard 224, pointer 226, miscellaneous input/output (I/O) devices 228, link 229, communications 230, and port 232. The bus system 202 may be for example, one or more of such buses as a system bus, Peripheral Component Interconnect (PCI), Advanced Graphics Port (AGP), Small Computer System Interface (SCSI), Institute of Electrical and Electronics Engineers (IEEE) standard number 1394 (FireWire), Universal Serial Bus (USB), etc. The CPU 204 may be a single, multiple, or even a distributed computing resource. Storage 210, may be Compact Disc (CD), Digital Versatile Disk (DVD), hard disks (HD), optical disks, tape, flash, memory sticks, video recorders, etc. Display 220 might be, for example, an embodiment of the present invention. Note that depending upon the actual implementation of a computer system, the computer system may include some, all, more, or a rearrangement of components in the block diagram. For example, a thin client might consist of a wireless hand held device that lacks, for example, a traditional keyboard. Thus, many variations on the system of FIG. 2 are possible.

For purposes of discussing and understanding the invention, it is to be understood that various terms are used by those knowledgeable in the art to describe techniques and approaches. Furthermore, in the description, for purposes of explanation, numerous specific details are set forth in order to provide a thorough understanding of the present invention. It will be evident, however, to one of ordinary skill in the art that the present invention may be practiced without these specific details. In some instances, well-known structures and devices are shown in block diagram form, rather than in detail, in order to avoid obscuring the present invention. These embodiments are described in sufficient detail to enable those of ordinary skill in the art to practice the invention, and it is to be understood that other embodiments may be utilized and that logical, mechanical, electrical, and other changes may be made without departing from the scope of the present invention.

Some portions of the description may be presented in terms of algorithms and symbolic representations of operations on, for example, data bits within a computer memory. These algorithmic descriptions and representations are the means used by those of ordinary skill in the data processing arts to most effectively convey the substance of their work to others of ordinary skill in the art. An algorithm is here, and generally, conceived to be a self-consistent sequence of acts leading to a desired result. The acts are those requiring physical manipulations of physical quantities. Usually, though not necessarily, these quantities take the form of electrical or magnetic signals capable of being stored, transferred, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise as apparent from the discussion, it is appreciated that throughout the description, discussions utilizing terms such as “processing” or “computing” or “calculating” or “determining” or “displaying” or the like, can refer to the action and processes of a computer system, or similar electronic computing device, that manipulates and transforms data represented as physical (electronic) quantities within the computer system's registers and memories into other data similarly represented as physical quantities within the computer system memories or registers or other such information storage, transmission, or display devices.

An apparatus for performing the operations herein can implement the present invention. This apparatus may be specially constructed for the required purposes, or it may comprise a general-purpose computer, selectively activated or reconfigured by a computer program stored in the computer. Such a computer program may be stored in a computer readable storage medium, such as, but not limited to, any type of disk including floppy disks, hard disks, optical disks, compact disk- read only memories (CD-ROMs), and magnetic-optical disks, read-only memories (ROMs), random access memories (RAMs), electrically programmable read-only memories (EPROM)s, electrically erasable programmable read-only memories (EEPROMs), FLASH memories, magnetic or optical cards, etc., or any type of media suitable for storing electronic instructions either local to the computer or remote to the computer.

The algorithms and displays presented herein are not inherently related to any particular computer or other apparatus. Various general-purpose systems may be used with programs in accordance with the teachings herein, or it may prove convenient to construct more specialized apparatus to perform the required method. For example, any of the methods according to the present invention can be implemented in hard-wired circuitry, by programming a general-purpose processor, or by any combination of hardware and software. One of ordinary skill in the art will immediately appreciate that the invention can be practiced with computer system configurations other than those described, including hand-held devices, multiprocessor systems, microprocessor-based or programmable consumer electronics, digital signal processing (DSP) devices, set top boxes, network PCs, minicomputers, mainframe computers, and the like. The invention can also be practiced in distributed computing environments where tasks are performed by remote processing devices that are linked through a communications network.

The methods of the invention may be implemented using computer software. If written in a programming language conforming to a recognized standard, sequences of instructions designed to implement the methods can be compiled for execution on a variety of hardware platforms and for interface to a variety of operating systems. In addition, the present invention is not described with reference to any particular programming language. It will be appreciated that a variety of programming languages may be used to implement the teachings of the invention as described herein. Furthermore, it is common in the art to speak of software, in one form or another (e.g., program, procedure, application, driver, . . . ), as taking an action or causing a result. Such expressions are merely a shorthand way of saying that execution of the software by a computer causes the processor of the computer to perform an action or produce a result.

It is to be understood that various terms and techniques are used by those knowledgeable in the art to describe communications, protocols, applications, implementations, mechanisms, etc. One such technique is the description of an implementation of a technique in terms of an algorithm or mathematical expression. That is, while the technique may be, for example, implemented as executing code on a computer, the expression of that technique may be more aptly and succinctly conveyed and communicated as a formula, algorithm, or mathematical expression. Thus, one of ordinary skill in the art would recognize a block denoting A+B=C as an additive function whose implementation in hardware and/or software would take two inputs (A and B) and produce a summation output (C). Thus, the use of formula, algorithm, or mathematical expression as descriptions is to be understood as having a physical embodiment in at least hardware and/or software (such as a computer system in which the techniques of the present invention may be practiced as well as implemented as an embodiment).

A machine-readable medium is understood to include any non-transitory mechanism for storing or transmitting information in a form readable by a machine (e.g., a computer). For example, a machine-readable medium includes read only memory (ROM); random access memory (RAM); magnetic disk storage media; optical storage media; flash memory devices; mechanical, electrical, optical, acoustical or other forms of non-transitory signals.

As used in this description, “one embodiment” or “an embodiment” or similar phrases means that the feature(s) being described are included in at least one embodiment of the invention. References to “one embodiment” in this description do not necessarily refer to the same embodiment; however, neither are such embodiments mutually exclusive. Nor does “one embodiment” imply that there is but a single embodiment of the invention. For example, a feature, structure, act, etc. described in “one embodiment” may also be included in other embodiments. Thus, the invention may include a variety of combinations and/or integrations of the embodiments described herein.

As used in this description, “substantially” or “substantially equal” or similar phrases are used to indicate that the items are very close or similar. Since two physical entities can never be exactly equal, a phrase such as “substantially equal” is used to indicate that they are for all practical purposes equal.

As used in this description “low power” or “lower power” or similar language refers to a comparison with the industry standard at the time of this invention.

As used in this description, “line code specification”, “line code” or similar language is understood by one of skill in the art to refer to the modulation method (code) for a signal for transmission on a particular type of transmission medium (line).

As used in this description “datastream” or “data stream” are considered to refer to a stream of data.

It is to be understood that in any one or more embodiments of the invention where alternative approaches or techniques are discussed that any and all such combinations as might be possible are hereby disclosed. For example, if there are five techniques discussed that are all possible, then denoting each technique as follows: A, B, C, D, E, each technique may be either present or not present with every other technique, thus yielding 2̂5 or 32 combinations, in binary order ranging from not A and not B and not C and not D and not E to A and B and C and D and E. Applicant(s) hereby claims all such possible combinations. Applicant(s) hereby submit that the foregoing combinations comply with applicable EP (European Patent) standards. No preference is given any combination.

Thus a method and apparatus for reduction of communications media energy consumption circuit have been described.

1. A method comprising:
switching at a first time a gate of an n-type field effect transistor in a transmission gate from a ground potential to a first high impedance wherein said first high impedance is connected to a power supply not at said ground potential;
switching at substantially said first time a body of said n-type field effect transistor in said transmission gate from said ground potential to a second high impedance wherein said second high impedance is connected directly only to a single input of said transmission gate and not directly to an output of said transmission gate, and wherein said n-type field effect transistor body is not connected to said output; and
wherein said transmission gate has no transistors for shorting said output of said transmission gate to said ground potential.

2. The method of claim 1 further comprising:
switching at substantially said first time a gate of a p-type field effect transistor in said transmission gate from said power supply not at said ground potential to a third high impedance wherein said third high impedance is connected to said ground potential; and
switching at substantially said first time a body of said p-type field effect transistor in said transmission gate from said power supply not at said ground potential to a fourth high impedance wherein said fourth high impedance is connected to said single input of said transmission gate, and wherein said p-type field effect transistor body is not connected to said output.

3. The method of claim 1 further comprising:
switching at a second time said gate of said n-type field effect transistor in said transmission gate from said first high impedance to said ground potential; and
switching at substantially said second time said body of said n-type field effect transistor in said transmission gate from said second high impedance to said ground potential.

4. The method of claim 2 further comprising:
switching at a second time said gate of said p-type field effect transistor in said transmission gate from said third high impedance to said power supply not at said ground potential; and
switching at substantially said second time said body of said p-type field effect transistor in said transmission gate from said fourth high impedance to said power supply not at said ground potential.

5. The method of claim 2 further comprising:
switching at a second time said gate of said n-type field effect transistor in said transmission gate from said first high impedance to said ground potential; and
switching at substantially said second time said body of said n-type field effect transistor in said transmission gate from said second high impedance to said ground potential.

6. The method of claim 5 further comprising:
switching at substantially said second time said gate of said p-type field effect transistor in said transmission gate from said third high impedance to said power supply not at said ground potential; and
switching at substantially said second time said body of said p-type field effect transistor in said transmission gate from said fourth high impedance to said power supply not at said ground potential.

7. A method for switching a transmission gate having an input and an output, the method comprising:
determining a state of a signal, said signal having an ON state and an OFF state; and
when said signal has said ON state;
connecting a gate of an n-type field effect transistor to a first high impedance wherein said first high impedance is connected to a power supply not at a ground potential;
connecting a body of said n-type field effect transistor to a second high impedance wherein said second high impedance is connected directly to only a single input and not directly to said output of said transmission gate, and wherein said n-type field effect transistor body is not connected to said output;
connecting a gate of a p-type field effect transistor to a third high impedance wherein said third high impedance is connected to said ground potential;
connecting a body of said p-type field effect transistor to a fourth high impedance wherein said fourth high impedance is connected to said single input, and wherein said p-type field effect transistor body is not connected to said output;
when said signal has said OFF state;
connecting said gate of said n-type field effect transistor to said ground potential;
connecting said body of said n-type field effect transistor to said ground potential;
connecting said gate of said p-type field effect transistor to said power supply not at said ground potential;
connecting said body of said p-type field effect transistor to said power supply not at said ground potential; and
wherein said transmission gate has no transistors for shorting said output of said transmission gate to said ground potential.

8. The method of claim 7 wherein said connecting said gate of said n-type field effect transistor and said connecting said body of said n-type field effect transistor occur at different times.

9. The method of claim 7 wherein said connecting said gate of said p-type field effect transistor and said connecting said body of said p-type field effect transistor occur at different times.

10. A transmission gate apparatus having a single input port and a single output port, the apparatus comprising:
an n-type field effect transistor having a gate, a source, a drain, and a body wherein said drain is connected directly to only said single input port and not directly to said single output port of said transmission gate, said source is connected to only said single output port;
a p-type field effect transistor having a gate, a source, a drain, and a body wherein said source is connected directly to said single input port and not directly to said single output port of said transmission gate, said drain is connected to said single output port;
a first switch being a single pole double throw switch, wherein said first switch single pole is connected to said n-type field effect transistor gate, wherein said first switch one throw is connected to a ground potential and said first switch an other throw is connected to a first high impedance which is connected to a power supply not at said ground potential;
a second switch being a single pole double throw switch, wherein said second switch single pole is connected to said n-type field effect transistor body, wherein said second switch one throw is connected to said ground potential and said second switch an other throw is connected to a second high impedance which is connected to said input, and wherein when in said other throw said n-type field effect transistor body is not connected to said output;
a third switch being a single pole double throw switch, wherein said third switch single pole is connected to said p-type field effect transistor gate, wherein said third switch one throw is connected to said power supply not at said ground potential and said third switch an other throw is connected to a third high impedance which is connected to said ground potential; and
a fourth switch being a single pole double throw switch, wherein said fourth switch single pole is connected to said p-type field effect transistor body, wherein said fourth switch one throw is connected to said power supply not at said ground potential and said fourth switch an other throw is connected to a fourth high impedance which is connected to said input, and wherein when in said other throw said p-type field effect transistor body is not connected to said output.

11. The apparatus of claim 10 wherein said first switch said second switch said third switch and said fourth switch are all ganged for switching purposes.

12. The apparatus of claim 10 wherein said first switch and said second switch are ganged such that connections to said ground are substantially made at a same time.

13. The apparatus of claim 10 wherein said third switch and said fourth switch are ganged such that connections to said power supply not at said ground potential are substantially made at a same time.

14. The apparatus of claim 10 wherein said first switch and said second switch are ganged such that connections to said ground or connections to said first high impedance and said second high impedance are substantially made at a same time and wherein said third switch and said fourth switch are ganged such that connections to said power supply not at said ground potential or connections to said third high impedance and said fourth high impedance are substantially made at said same time.

15. The apparatus of claim 10 wherein said first switch and said second switch are ganged such that connections to said first high impedance and said second high impedance are substantially made at a same time.

16. The apparatus of claim 10 wherein said third switch and said fourth switch are ganged such that connections to said third high impedance and said fourth high impedance are substantially made at a same time.
